(19) United States
(12) Patent Application Publication
(10) Pub. No.: US 2025/0385102 A1
(43) Pub. Date: Dec. 18, 2025

(54) PACKAGING SUBSTRATE SELECTIVE SURFACE MORPHOLOGY

(71) Applicant: SKYWORKS SOLUTIONS, INC., Irvine, CA (US)

(72) Inventors: Chien Jen WANG, Taoyuan City (TW); Jae Hyung PARK, Ansan-si (KR)

(21) Appl. No.: 19/234,621

(22) Filed: Jun. 11, 2025

Related U.S. Application Data
(60) Provisional application No. 63/660,792, filed on Jun. 17, 2024.

(51) Int. Cl. H01L 21/48; G03F 7/00; G03F 7/40; H01L 23/538

(52) U.S. Cl. CPC H01L 21/4846; G03F 7/0012; G03F 7/40; H01L 23/5386

(57) ABSTRACT

According to certain aspects, devices and methods can be provided for forming packaging substrates having selective surface morphology. For instance, a method of implementing a packaging substrate can include: providing a packaging substrate including a first side and a second side, one or more of the first side and the second side configured to receive components; applying a surface finish for input/output connections on one or more of the first side and the second side; applying a patterning process to one or more of the first side and the second side to expose areas for applying a surface post treatment; and applying the surface post treatment to one or more of the first side and the second side such that the packaging substrate includes portions of surfaces having different surface morphologies.

### BACKGROUND

### Field

The present disclosure generally relates to substrates, for example, for packaged electronic modules.

### Description of the Related Art

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components.

### SUMMARY

According to some implementations, the present disclosure relates to a method of implementing a packaging substrate. The method can include providing a packaging substrate including a first side and a second side, where one or more of the first side and the second side are configured to receive components. The method can further include applying a surface finish for input/output connections on one or more of the first side and the second side. The method can also include applying a patterning process to one or more of the first side and the second side to expose areas for applying a surface post treatment. The method can additionally include applying the surface post treatment to one or more of the first side and the second side such that the packaging substrate includes portions of surfaces having different surface morphologies.

In some examples, the patterning process can include a photo image transfer process that applies a photo imageable film to one or more of the first side or the second side. For instance, the photo image transfer process can transfer a pattern to the photo imageable film. In certain examples, the method can further include removing the photo imageable film after applying the surface post treatment to one or more of the first side and the second side.

In certain examples, the surface post treatment can include one or more of plasma or pumice. In certain examples, the first side and the second side may include portions having different surface morphologies. In some examples, the first side or the second side may include portions having different surface morphologies.

In some examples, the surface finish can include electroless nickel/electroless palladium/immersion gold (ENEPIG). In certain examples, the method can further include mounting one or more components on one or more of the first side and the second side.

According to certain implementations, the present disclosure relates to a packaging substrate. The packaging substrate can include a first side and a second side. The packaging substrate can have portions on one or more of the first side and the second side having different surface morphologies, where the different surface morphologies can result from application of a patterning process that exposes areas for applying a surface post treatment on one or more of the first side and the second side.

In some examples, the patterning process can include a photo image transfer process that applies a photo imageable film to one or more of the first side or the second side. For instance, the photo image transfer process can transfer a pattern to the photo imageable film.

In certain examples, the surface post treatment can include one or more of plasma or pumice. In certain examples, the first side and the second side may include portions having different surface morphologies. In some examples, the first side or the second side may include portions having different surface morphologies.

In some examples, a surface finish can be applied to input/output connections on one or more of the first side and the second side. For instance, the surface finish can include electroless nickel/electroless palladium/immersion gold (ENEPIG). In certain examples, one or more components may be mounted on one or more of the first side and the second side.

According to some implementations, the present disclosure relates to a method of implementing a packaging substrate. The method can include providing a packaging substrate including a first side and a second side, where one or more of the first side and the second side are configured to receive components. The method can also include applying a patterning process to one or more of the first side and the second side to expose areas for applying a surface post treatment. The method can further include applying the surface post treatment to one or more of the first side and the second side such that the packaging substrate includes portions of surfaces having different surface morphologies.

In some examples, the patterning process can include a photo image transfer process that applies a photo imageable film to one or more of the first side or the second side.

### BRIEF DESCRIPTION OF THE DRAWINGS

FIG. 1 is a diagram illustrating certain problems associated with surface morphology of packaging substrates, in accordance with one or more embodiments.

FIG. 2 is a diagram illustrating example packaging substrate surface morphologies and associated surface roughness, in accordance with one or more embodiments.

FIGS. 3A to 3D are block diagrams that show various stages of a process that can implement selective surface morphology for a packaging substrate, in accordance with one or more embodiments.

FIG. 4 illustrates a process that can be implemented to provide selective surface morphology, in accordance with one or more embodiments.

FIG. 5 depicts an example wireless device having one or more advantageous features described herein, in accordance with one or more embodiments.

### DETAILED DESCRIPTION

The headings provided herein, if any, are for convenience only and do not necessarily affect the scope or meaning of the claimed invention.

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. For example, a packaging substrate can be a printed circuit board (PCB). One or more components can be mounted on the upper side of the packaging substrate, and an upper overmold can be provided to encapsulate such components. One or more components may also be mounted on the lower side of the packaging substrate, and a lower overmold can be provided to encapsulate such components. In some embodiments, a packaged module can be a dual-sided module.

Other than metal input/output (I/O) pins, a surface of a packaging substrate can be a combination of dielectric and solder resist to protect metal features underneath. Each material can have its own surface morphology based on a packaging substrate process flow. During package assembly, several process steps/materials can contact one or both surfaces on upper and/or lower sides of a packaging substrate. The packaging substrate surface morphology may result in different behaviors of the assembly materials, such as flow rate, diffuse velocity, etc. Accordingly, the package assembly may be limited in material selection and/or process window.

Packaging substrate manufacturers can apply post treatments to a surface of a packaging substrate in order to change surface morphology or surface tension. Examples of post treatments may include plasma, pumice, etc. However, any of such post treatments applies to the entire surface area on both upper and lower sides such that the surface can only be optimized for a single package assembly factor. Therefore, according to certain aspects, the present disclosure relates to providing packaging substrates having selective surface morphology or different surface morphologies.

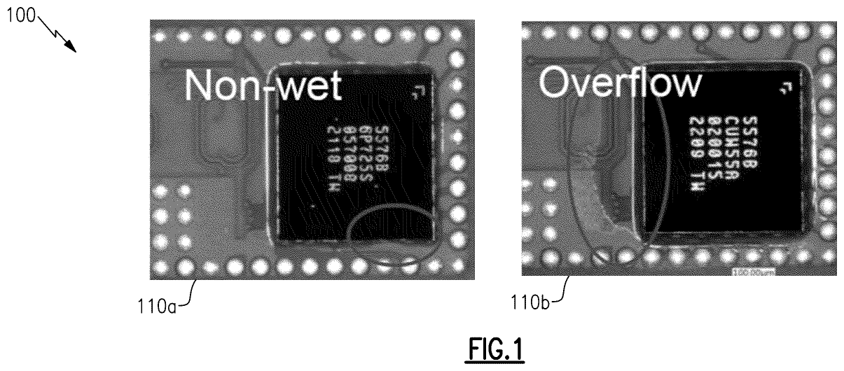

FIG. 1 is a diagram 100 illustrating certain problems associated with surface morphology of packaging substrates. For example, a packaging substrate can be a printed circuit board (PCB). A packaging substrate can include a plurality of conductive layers. For instance, the layers may be made of copper (Cu). Other materials may be used to form the layers depending on the embodiment. The layers can include one or more inner layers and one or more outer layers. The packaging substrate can also include other layers and features, such as dielectric layers, passive components (such as resistors, capacitors, and inductors), conductor features (such as vias and traces), and a ground plane. A packaging substrate can have a first side and a second side. For illustrative purposes, the first side and the second side may be referred to as a top or upper side and a bottom or lower side, respectively, depending on the orientation. A packaging substrate can receive one or more components on either or both of the upper side and the lower side. For instance, a packaging substrate may be used to form dual-sided modules.

According to certain aspects, surface morphology can refer to a shape of a surface of a packaging substrate. For example, each side or an outer layer of a packaging substrate can have a corresponding surface morphology. A surface can be represented by peaks and/or valleys (e.g., ridges and/or grooves). For instance, higher peaks (or deeper valleys) can represent a rougher surface, and lower peaks (or shallower valleys) can represent a smoother surface. Peaks and/or valleys may be used to determine various measurements or parameters associated with roughness of a surface, such as roughness average (Ra), peak count or density, etc. Roughness average may refer to an average of roughness of a surface, for example, based on heights of peaks and/or depths of valleys. Peak count may refer to a number of peaks and/or valleys of a surface for a specified unit length, area, etc.

Except for metal I/O pins or connections, a surface of a packaging substrate may include dielectric and solder resist to protect metal features underneath. Each material can have its own surface morphology based on a packaging substrate process flow. During package assembly, several process steps/materials can contact one or both surfaces on upper and/or lower sides of a packaging substrate. The packaging substrate surface morphology may result in different behaviors and/or characteristics of the assembly materials. For example, flow rate, diffuse velocity, and other factors can differ depending on surface morphology. Accordingly, the package assembly may be limited in material selection, process window, and/or design rules. According to certain aspects, a process window may refer to a range or values of parameters for a manufacturing process that provides defined results or specifications. Some examples of different parameters may include pressure, temperature, etc.

Different packaging substrate surface morphologies can result in different behaviors during a package assembly process. As an example, a packaging substrate 110b in the right picture of the diagram 100 can have a surface morphology that causes die attach epoxy to overflow and bleed out. As another example, a packaging substrate 110a on the left picture of the diagram 100 can have a surface morphology that leads to non-wetting defects for solder balls. For instance, die attach epoxy can flow out to the solder ball area and result in non-wetting defects for solder balls. As an additional example, if plasma is applied to clean wire bond gold (Au) surface, roughness of solder mask (SM) can be changed at the same time, which can cause die attach epoxy to bleed out.

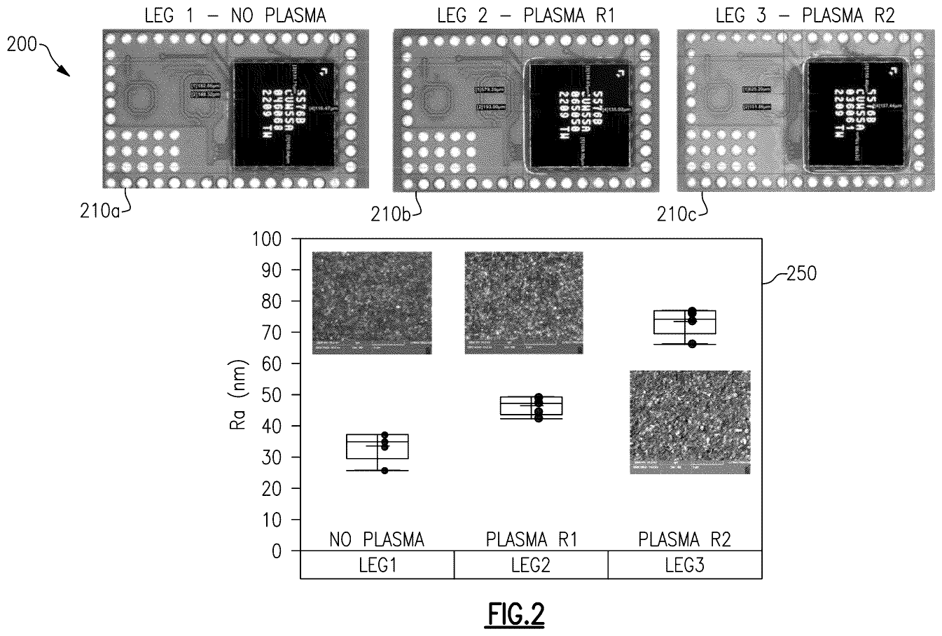

FIG. 2 is a diagram 200 illustrating example packaging substrate surface morphologies and associated surface roughness. As explained above, surface morphology of a packaging substrate can impact an assembly process. A post treatment, such as plasma, pumice, or other types of treatments, can be applied to a packaging substrate in order to change surface morphology or surface tension. For example, post treatments may be applied by packaging substrate manufacturers. The diagram 200 shows example packaging substrates 210 and corresponding surface morphologies with various treatments applied. The diagram 200 also includes a chart 250 showing surface morphologies and Ra of the different packaging substrates 210.

On a surface of a packaging substrate, a surface finish (e.g., Au or other types of finish) can be applied to areas for I/O connections. Solder resist can be applied to rest of areas including copper patterns. To provide good adhesion with solder resist, a surface treatment can be applied to create roughness either on copper surface or dielectric surface. According to certain aspects, such treatment may be referred to as a post treatment.

In the example of FIG. 2, treatments can include no plasma, a first plasma (R1), and a second plasma (R2). Different treatments or recipes can create different surface morphology or surface roughness. Depending on the process or material, a desired roughness may be lower or higher. For example, for a die attach process, a lower surface roughness may be desired. For other types of processes, a higher surface roughness may be desired. In general, any post treatment is applied to the entire surface area on both upper and lower sides of the packaging substrate such that the surface can only be optimized for a single package assembly factor or parameter. This can limit material selection, assembly parameters, and/or design rules. As an example, in order to facilitate a material, design density may need to be decreased, a wider keep-out zone may need to be maintained, etc.

The diagram 200 shows example packaging substrates 210a, 210b, 210c with no plasma, plasma R1, and plasma R2 applied as post treatments, respectively. Legs 1, 2, 3 can refer to different legs relating to design of experiments (DOE). According to certain aspects, DOE may refer to a process of determining factors and desired effects or results. A leg may refer to different conditions or values of a single factor or multiple factors. The chart 250 shows surface morphologies corresponding to the packaging substrates 210a, 210b, 210c and corresponding Ra. Ra is indicated in nanometers (nm). The Ra value of the packaging substrate 210a is about 35 nm. The Ra of the packaging substrate 210b is about 45 nm. The Ra of the packaging substrate 210c is about 75 nm. The packaging substrate 210a has a smoother surface morphology than the packaging substrate 210b and the packaging substrate 210c, and the packaging substrate 210b has a smoother surface morphology than the packaging substrate 210c.

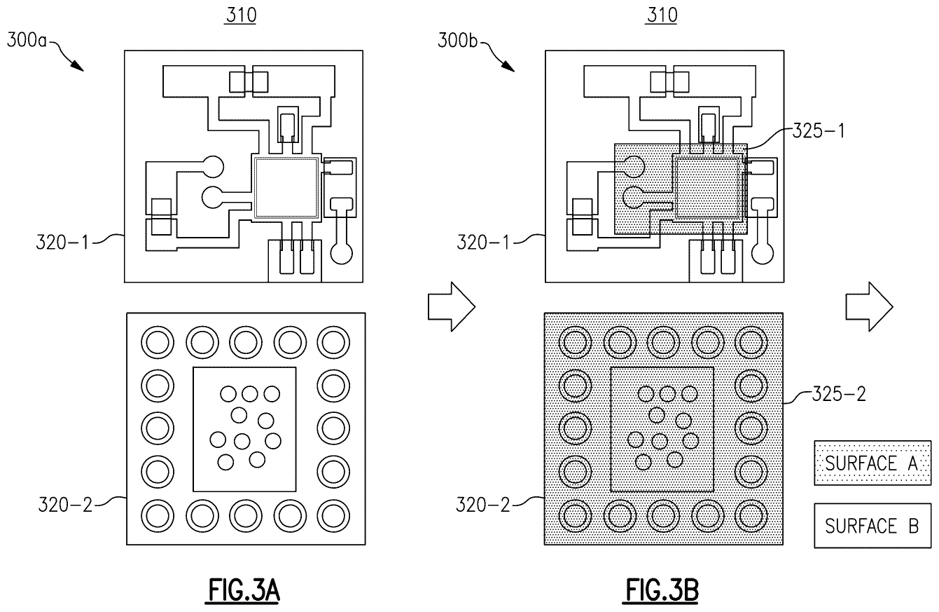

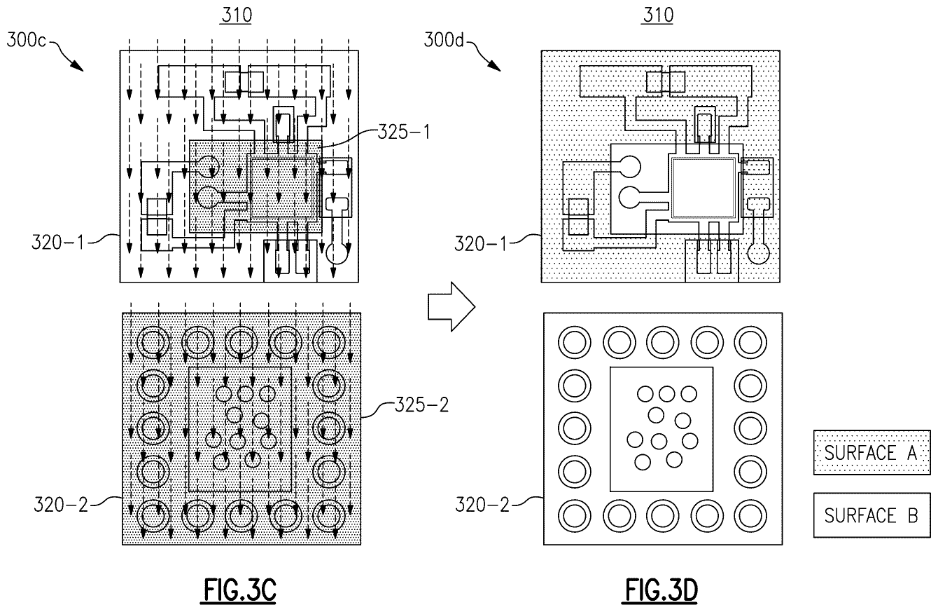

FIGS. 3A to 3D are block diagrams 300a-300d that show various stages of a process that can implement selective surface morphology for a packaging substrate 310. Certain aspects and details relating to the packaging substrate 310 and providing selective surface morphology are described in connection with FIGS. 1-2. For example, similar names and/or reference numbers may refer to similar parts or features.

A patterning process may be used for a packaging substrate 310 in order to create copper patterns. For example, a surface of a packaging substrate 310 may be covered with copper, and a photo imageable film, such as a dry film, can be used to cover the copper to create a pattern. A desired pattern can be transferred to the photo imageable film in an image transfer process. For instance, area(s) of the copper to be etched can be exposed by the photo imageable film. Then, copper etching can be performed. After the photo imageable film is stripped, the copper pattern is shown on the surface. Such or similar patterning processes may be used to create different surface morphologies on a surface of a packaging substrate 310.

After I/O pin surface finish is completed, another patterning or image transfer process (e.g., photo imageable film) can be applied to expose only desirable area(s) of a surface of a packaging substrate 310 for post treatment. For instance, the photo imageable film can include a dry film or any suitable material. A desired pattern for post treatment can be transferred to the photo imageable film in an image transfer process and expose area(s) to which a post treatment should be applied. A post treatment can then be applied to exposed area(s) of the surface of the packaging substrate 310. Examples of a post treatment can include plasma, pumice, etc. as mentioned above. A post treatment may include any appropriate surface treatment that can be applied to a surface of a packaging substrate. After the photo imageable film is removed, the packaging substrate 310 can have two different surface morphologies. The post treatment can be applied to one or both of the upper side and lower side of the packaging substrate 310. Depending on the pattern of the photo imageable film, different surface morphologies can be on the same side or different sides of the packaging substrate 310, etc. Accordingly, by using an additional image transfer process, selective surface morphology can be provided for the packaging substrate 310.

Various stages of the process for implementing selective surface morphology are further explained in connection with FIGS. 3A-3D. FIGS. 3A-3D illustrate respective surfaces 320-1 and 320-2 of the upper and lower sides of the packaging substrate 310. The process can be applied to one or both of the upper and lower sides of the packaging substrate 310. In the example of FIGS. 3A-3D, the process for implementing selective surface morphology is applied to both sides of the packaging substrate 310. A surface 320-1, 320-2 can include various features, such as conductive pads, conductive trace, etc. In the example of FIGS. 3A-3D, a surface having a first surface morphology is indicated as Surface A, and a surface having a second surface morphology that is different from the first surface morphology is indicated as Surface B.

In FIG. 3A, a surface finish can be applied to I/O pins or connections on the surface of the packaging substrate 310. As an example, ENEPIG can be applied to the I/O pins. The surface finish may include any appropriate material. Both the surface 320-1 of the upper side and the surface 320-2 of the lower side have a surface morphology indicated as Surface B.

In FIG. 3B, a photo image transfer process can be applied to the packaging substrate 310 in order to expose areas of the surface of the packaging substrate 310 to which a post treatment will be applied. For instance, the photo image transfer process can cover areas to which the post treatment will not be applied. A pattern for applying the post treatment can be transferred to the photo imageable film (e.g., dry film) and expose areas to which the post treatment will be applied. In the example of FIG. 3B, the surface 320-1 of the upper side of the packaging substrate 310 is partially covered with the photo imageable film 325-1, and the surface 320-2 of the lower side of the packaging substrate 310 is completely covered with the photo imageable film 325-2. Any appropriate pattern can be used. Portions of the surface 320-1 and 320-2 not covered by the photo imageable film 325-1 and 325-2 have a surface morphology indicated as Surface B. Portions of the surface 320-1 and 320-2 under the photo imageable film 325-1 and 325-2 also have a surface morphology indicated as Surface B.

In FIG. 3C, a post treatment can be applied to the exposed surface of the packaging substrate 310. A post treatment can include plasma, pumice, or any suitable treatment. For instance, a post treatment can be a mechanical treatment, a chemical treatment, etc. In some cases, chemical etching can be applied to change surface roughness or thickness. In the example of FIG. 3C, the post treatment is applied to portions of the surface 320-1 of the upper side of the packaging substrate 310 and the surface 320-2 of the lower side of the packaging substrate 310 that are not covered by the photo imageable film 325-1 and 325-2.

In FIG. 3D, the photo imageable film is removed or stripped off from the surface of the packaging substrate 310. In the example of FIG. 3D, after the photo imageable film is removed, the packaging substrate 310 has two different surface morphologies on the upper and/or lower sides of the packaging substrate 310. The surface 320-1 of the upper side of the packaging substrate 310 has a portion having a surface morphology indicated as Surface A and a portion having a surface morphology indicated as Surface B. Since the surface 320-2 of the lower side of the packaging substrate 310 was covered, the surface 320-2 has a surface morphology indicated as Surface B. In this way, a packaging substrate having two different surface morphologies can be created, and selective surface morphology can be provided for a packaging substrate. The process for implementing selective surface morphology may be performed during packaging substrate manufacturing, package assembly, etc. For example, a post treatment may be applied by a packaging substrate manufacturer to a PCB panel. As another example, a post treatment may be applied by an entity using a packaging substrate during a package assembly process.

In some implementations, the patterning or photo image transfer process for a post treatment can be iterated to provide additional surface morphologies. For example, a photo image transfer process can be applied after the first photo image transfer process such that the packaging substrate can have three different surface morphologies.

In general, a post treatment can be applied to the entire surface on one or both sides of a packaging substrate. Accordingly, surface morphology can be optimized for a single assembly parameter, for example, the most critical parameter. Other parameters may be sacrificed or addressed by reducing design density, limiting material selection, and so forth. By providing surfaces having different surface morphologies, the present disclosure can enable an assembly process to be optimized for multiple parameters, for example, two or more parameters. Accordingly, limitations on material selection, process window, design rules, etc. can be reduced.

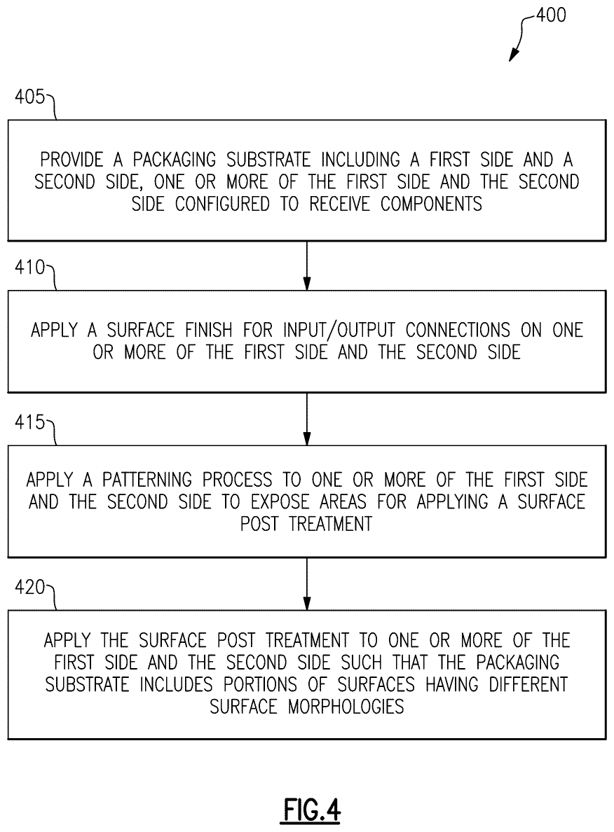

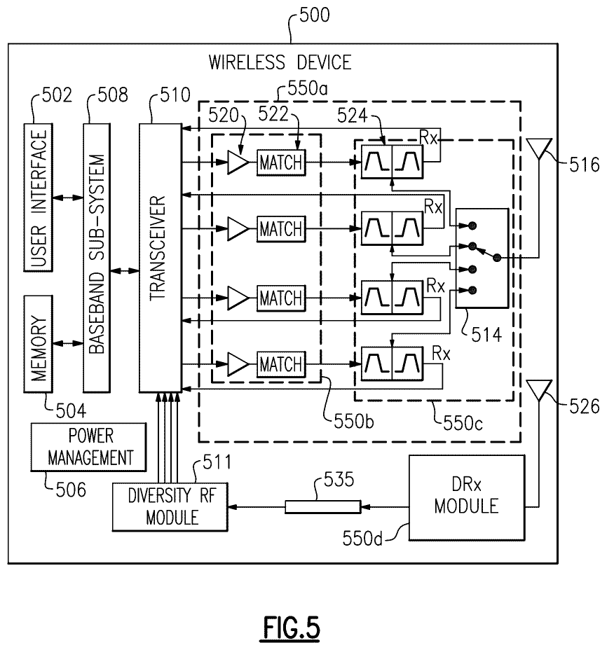

FIG. 4 shows a process 400 that can be implemented to provide selective surface morphology as described herein. Certain details relating to the process 400 are explained in more detail with respect to FIGS. 1-3. Depending on the embodiment, the process 400 may include fewer or additional blocks, and the blocks may be performed in an order that is different from illustrated.

At block 405, the process 400 can provide a packaging substrate including a first side and a second side, where one or more of the first side and the second side are configured to receive components.

At block 410, the process 400 can apply a surface finish for input/output connections on one or more of the first side and the second side. In some cases, the surface finish includes electroless nickel/electroless palladium/immersion gold (ENEPIG). In some embodiments, applying the surface finish for the input/output connections on one or more of the first side and the second side may be optional.

At block 415, the process 400 can apply a patterning process to one or more of the first side and the second side to expose areas for applying a surface post treatment. In some cases, the patterning process can include a photo image transfer process that applies a photo imageable film to one or more of the first side or the second side. For instance, the photo image transfer process can transfer a pattern to the photo imageable film.

At block 420, the process 400 can apply the surface post treatment to one or more of the first side and the second side such that the packaging substrate includes portions of surfaces having different surface morphologies. In some embodiments, the surface post treatment includes one or more of plasma or pumice. In some cases, the first side and the second side include portions having different surface morphologies. In certain cases, the first side or the second side includes portions having different surface morphologies.

In some embodiments, the process 400 can remove the photo imageable film after applying the surface treatment to one or more of the first side and the second side. In certain embodiment, the process 400 can mount one or more components on one or more of the first side and the second side.

Selective surface morphology for packaging substrates as described herein can be used to provide packaged modules, such as dual-sided modules. Examples related to upper side and/or lower side configurations of packaged modules, as well as examples related to fabrication methods where a plurality of units can be fabricated in an array format, are described in U.S. Publication No. 2022/0319968, entitled “MODULE HAVING DUAL SIDE MOLD WITH METAL POSTS” and U.S. Publication No. 2018/0096949, entitled “DUAL-SIDED RADIO-FREQUENCY PACKAGE WITH OVERMOLD STRUCTURE,” each of which is hereby expressly incorporated by reference in its entirety. In some embodiments, at least some of the examples provided in U.S. Publication No. 2022/0319968 and U.S. Publication No. 2018/0096949 can utilize packaging substrates having selective surface morphology and having one or more features as described herein. Such packaged modules may be mounted on a circuit board.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

FIG. 5 depicts an example wireless device 500 having one or more advantageous features described herein. In the example of FIG. 5, an RF module having one or more features as described herein can be implemented in a number of places. For example, an RF module may be implemented as a front-end module (FEM) indicated as 550a. In another example, an RF module may be implemented as a power amplifier module (PAM) indicated as 550b. In another example, an RF module may be implemented as an antenna switch module (ASM) indicated as 550c. In another example, an RF module may be implemented as a diversity receive (DRx) module indicated as 550d. It will be understood that an RF module having one or more features as described herein can be implemented with other combinations of components.

Referring to FIG. 5, power amplifiers (PAs) 520 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 can also be in communication with a power management component 506 that is configured to manage power for the operation of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, outputs of the PAs 520 are shown to be matched (via respective match circuits 522) and routed to their respective duplexers 524. Such amplified and filtered signals can be routed to a primary antenna 516 through an antenna switch 514 for transmission. In some embodiments, the duplexers 524 can allow transmit and receive operations to be performed simultaneously using a common antenna (e.g., primary antenna 516). In FIG. 5, received signals are shown to be routed to “Rx” paths that can include, for example, a low-noise amplifier (LNA).

In the example of FIG. 5, the wireless device 500 also includes the diversity antenna 526 and the shielded DRx module 550d that receives signals from the diversity antenna 526. The shielded DRx module 550d processes the received signals and transmits the processed signals via a transmission line 535 to a diversity RF module 511 that further processes the signal before feeding the signal to the transceiver 510.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of implementing a packaging substrate, the method comprising:
providing a packaging substrate including a first side and a second side, one or more of the first side and the second side configured to receive components;
applying a surface finish for input/output connections on one or more of the first side and the second side;
applying a patterning process to one or more of the first side and the second side to expose areas for applying a surface post treatment; and
applying the surface post treatment to one or more of the first side and the second side such that the packaging substrate includes portions of surfaces having different surface morphologies.

2. The method of claim 1 wherein the patterning process includes a photo image transfer process that applies a photo imageable film to one or more of the first side or the second side.

3. The method of claim 2 wherein the photo image transfer process transfers a pattern to the photo imageable film.

4. The method of claim 2 further comprising removing the photo imageable film after applying the surface post treatment to one or more of the first side and the second side.

5. The method of claim 1 wherein the surface post treatment includes one or more of plasma or pumice.

6. The method of claim 1 wherein the first side and the second side include portions having different surface morphologies.

7. The method of claim 1 wherein the first side or the second side includes portions having different surface morphologies.

8. The method of claim 1 wherein the surface finish includes electroless nickel/electroless palladium/immersion gold (ENEPIG).

9. The method of claim 1 further comprising mounting one or more components on one or more of the first side and the second side.

10. A packaging substrate comprising:
a first side; and
a second side, the packaging substrate having portions on one or more of the first side and the second side having different surface morphologies, the different surface morphologies resulting from application of a patterning process that exposes areas for applying a surface post treatment on one or more of the first side and the second side.

11. The packaging substrate of claim 10 wherein the patterning process includes a photo image transfer process that applies a photo imageable film to one or more of the first side or the second side.

12. The packaging substrate of claim 11 wherein the photo image transfer process transfers a pattern to the photo imageable film.

13. The packaging substrate of claim 10 wherein the surface post treatment includes one or more of plasma or pumice.

14. The packaging substrate of claim 10 wherein the first side and the second side include portions having different surface morphologies.

15. The packaging substrate of claim 10 wherein the first side or the second side includes portions having different surface morphologies.

16. The packaging substrate of claim 10 wherein a surface finish is applied to input/output connections on one or more of the first side and the second side.

17. The packaging substrate of claim 16 wherein the surface finish includes electroless nickel/electroless palladium/immersion gold (ENEPIG).

18. The packaging substrate of claim 10 further comprising one or more components mounted on one or more of the first side and the second side.

19. A method of implementing a packaging substrate, the method comprising:
providing a packaging substrate including a first side and a second side;
applying a patterning process to one or more of the first side and the second side to expose areas for applying a surface post treatment; and
applying the surface post treatment to one or more of the first side and the second side such that the packaging substrate includes portions of surfaces having different surface morphologies.

20. The method of claim 19 wherein the patterning process includes a photo image transfer process that applies a photo imageable film to one or more of the first side or the second side.
